(19) United States
(12) Patent Application Publication
(10) Pub. No.: US 2018/0287063 A1
(43) Pub. Date: Oct. 4, 2018

(54) DEPOSITION MASK AND DEPOSITION APPARATUS USING THE SAME

(71) Applicant: LG DISPLAY CO., LTD., Seoul (KR)

(72) Inventors: SeokRak CHANG, Seoul (KR); Hyunsook PARK, Seoul (KR); JongHeon KIM, Seoul (KR)

(73) Assignee: LG DISPLAY CO., LTD., Seoul (KR)

(21) Appl. No.: 15/925,309

(22) Filed: Mar. 19, 2018

(30) Foreign Application Priority Data
Mar. 31, 2017 (KR) 10-2017-0041722

(51) Int. Cl. H01L 51/00; H01L 51/56

(52) U.S. Cl. CPC H01L 51/0011; H01L 51/56; H01L 51/0012; H01L 51/0017

(57) ABSTRACT

A deposition mask can include a base member including a first surface and a second surface, which is divided into a first region, a second region and a third region; a first opening in the first region; a second opening in the second region; and a third opening in the third region, in which each of the first, second and third openings can have a cross-section having an hourglass shape, in which the hourglass shapes of the first and third openings lean away from the second opening relative to the second surface of the base member. In this way, a shadow effect can be minimized during a deposition process and deposition uniformity can be improved.

### CROSS REFERENCE TO RELATED APPLICATION

This application claims priority from Korean Patent Application No. 10-2017-0041722, filed in the Republic of Korea on Mar. 31, 2017, which is hereby incorporated by reference for all purposes as if fully set forth herein.

### BACKGROUND OF THE INVENTION

### 1. Field of the Invention

The present embodiments relate to a deposition mask and a deposition apparatus using the same, which can be applied to a deposition process.

### 2. Description of the Related Art

According to development of an information-oriented society, an electronic device, such as a new display device, lighting device, semiconductor device, or the like, needs to be developed.

An electronic device as described above includes at least one substrate, and a plurality of fine patterns are arranged on the substrate. A deposition apparatus is used to perform a deposition process using a deposition mask including a plurality of openings in order to form a fine pattern.

Due to the characteristics of a deposition apparatus used during a deposition process, an electronic device having a larger area may have a larger shadow effect caused by a deposition mask, which may degrade the deposition uniformity. Therefore, a deposition mask and a deposition apparatus using the same, which can minimize a shadow effect of an electronic device having a large area during a deposition process and thus improve the deposition uniformity, are desired.

### SUMMARY OF THE INVENTION

An aspect of embodiments of the present invention is to provide a deposition mask and a deposition apparatus using the same which can minimize a shadow effect during a deposition process and thus improve the deposition uniformity.

A deposition mask according to an embodiment of the present invention includes: a base member including a first surface and a second surface, the base member being divided into a first region, a second region and a third region; a first opening in the first region and comprising: a first surface hole of the first opening extending through the first surface of the base member, and a second surface hole of the first opening extending through the second surface of the base member and in communication with the first surface hole of the first opening, a width of the first surface hole of the first opening gradually decreases toward a border between the first surface hole of the first opening and the second surface hole of the first opening, and a width of the second surface hole of the first opening gradually decreases toward the border between the first surface hole of the first opening and the second surface hole of the first opening; a second opening in the second region and comprising: a first surface hole of the second opening extending through the first surface of the base member, and a second surface hole of the second opening extending through the second surface of the base member and in communication with the first surface hole of the second opening, a width of the first surface hole of the second opening gradually decreases toward a border between the first surface hole of the second opening and the second surface hole of the second opening, and a width of the second surface hole of the second opening gradually decreases toward the border between the first surface hole of the second opening and the second surface hole of the second opening; and a third opening in the third region and comprising: a first surface hole of the third opening extending through the first surface of the base member, and a second surface hole of the third opening extending through the second surface of the base member and in communication with the first surface hole of the third opening, a width of the first surface hole of the third opening gradually decreases toward a border between the first surface hole of the third opening and the second surface hole of the third opening, and a width of the second surface hole of the third opening gradually decreases toward the border between the first surface hole of the third opening and the second surface hole of the third opening, wherein step heights of both side surfaces of the first surface hole of the second opening are substantially equal to each other, wherein a step height of a side surface of the first surface hole in the first opening adjacent to the second opening is smaller than the step heights of both side surfaces of the first surface hole in the second opening, wherein a step height of a side surface of the first surface hole in the third opening adjacent to the second opening is smaller than the step heights of both side surfaces of the first surface hole in the second opening, and wherein the second region is located between the first region and the third region.

A deposition apparatus according to an embodiment of the present invention includes: a chamber including a deposition workspace for a substrate; a deposition source in the chamber and configured to supply a deposition material; and the above-mentioned deposition mask.

A deposition mask according to an embodiment includes a base member and openings.

The base member may include a first surface and a second surface and can be divided into at least a first region, a second region and a third region. The openings may include a first opening, a second opening and a third opening.

The first, second and third openings can be located at the first, second and third regions, respectively, and each of the first, second and third openings may include a first surface hole and a second surface hole which extend through the first surface and the second surface of the base member, are mutually open to each other, and have widths, each of which gradually decreases toward a border between the first and second surface holes in a thickness direction of the base member.

Step heights of both side surfaces of the first surface hole of the second opening located at the second region between the first region and the third region may be equal to each other, and a step height of a side surface nearest or in a direction toward the second opening among both side surfaces of the first surface hole of each of the first opening and the third opening may be smaller than the step heights of both side surfaces of the first surface hole of the second opening.

A deposition apparatus according to another embodiment can include: a chamber configured to provide a deposition work space for a substrate; a deposition source installed in the chamber and configured to supply a deposition material; and the above deposition mask disposed at one surface of the substrate.

A deposition mask and a deposition apparatus using the same according to the present embodiments can minimize a shadow effect during a deposition process and thus improve the uniformity of the deposition.

### BRIEF DESCRIPTION OF THE DRAWINGS

The above and other aspects, features and advantages of the present disclosure will be more apparent from the following detailed description taken in conjunction with the accompanying drawings, in which:

FIG. 1 is a cross-sectional view of a deposition apparatus according to an embodiment of the present invention;

FIG. 2 is a perspective view of a deposition mask according to another embodiment of the present invention;

FIG. 3 is a view showing a cross section taken along I-I′, II-II′, and III-III′ of FIG. 2 and a cross section of a substrate according to an embodiment of the present invention;

FIG. 4 illustrates a cross section of a deposition mask, a cross section of a substrate, and a deposition path according to a comparative example;

FIG. 5 illustrates a deposition path of the deposition mask illustrated in FIG. 3 according to an embodiment of the present invention;

FIG. 6 illustrates a comparison of shadow effects according to a difference between step heights of side surfaces of openings of the deposition mask illustrated in FIG. 3 and the deposition mask illustrated in FIG. 4 according to an embodiment of the present invention;

FIGS. 7A to 7E are diagrams illustrating a method of manufacturing a deposition mask according to another embodiment of the present invention;

FIG. 8 is a perspective view of a deposition mask according to another embodiment and illustrates relative positions of the deposition mask and a deposition source; and

FIG. 9 is a view showing a cross section of a deposition mask and a cross section of a substrate according to another embodiment of the present invention.

### DETAILED DESCRIPTION OF THE EMBODIMENTS

Hereinafter, embodiments of the present disclosure will be described in detail with reference to the accompanying drawings. The following embodiments are provided, by way of example, so that the idea of the present disclosure can be sufficiently conveyed to those skilled in the art. Therefore, the present disclosure is not limited to the embodiments as described below, and may be embodied in other forms. Also, in the drawings, the size, thickness, and the like of an apparatus may be exaggeratedly represented for the convenience of description. Throughout the specification, the same reference numerals designate the same elements.

The advantages and features of the present disclosure and methods of achieving the same will be apparent by referring to embodiments as described below in detail in conjunction with the accompanying drawings. However, the present disclosure is not limited to the embodiments set forth below, but may be implemented in various different forms. The following embodiments are provided only to completely disclose the present disclosure and inform those skilled in the art of the scope of the present disclosure, and the present disclosure is defined only by the scope of the appended claims. Throughout the specification, the same or like reference numerals designate the same or like elements. In the drawings, the dimensions and relative sizes of layers and regions may be exaggerated for the convenience of description.

When an element or layer is referred to as being “above” or “on” another element, it can be “directly above” or “directly on” the other element or layer or intervening elements or layers may be present. In contrast, when an element is referred to as being “directly on” or “directly above” another element or layer, there are no intervening elements or layers present.

Spatially relative terms, such as “below,” “beneath,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the element in use or operation in addition to the orientation depicted in the figures. For example, if the element in the figures is turned over, elements described as “below” or “beneath” other elements would then be oriented “above” the other elements. Thus, the exemplary term “below” can encompass both an orientation of above and below.

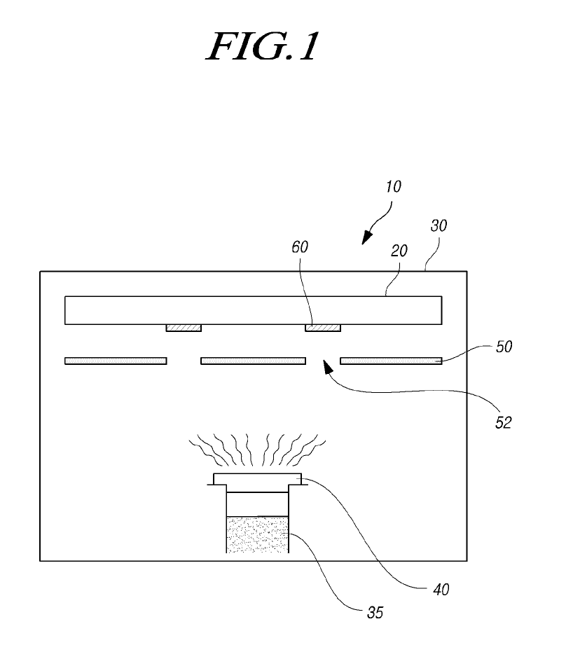

FIG. 1 is a cross-sectional view of a deposition apparatus according to an embodiment.

Referring to FIG. 1, a deposition apparatus 10 according to an embodiment includes a chamber 30 that provides a deposition work space for a substrate 20; a deposition source 40 that is installed in the chamber 30 and provides a deposition material 35; and a deposition mask 50 disposed at one surface of the substrate 20.

The deposition source 40 may be a point source having a point type in which a source is located at the middle of the deposition mask 50 and may be a linear source having a bar type in which a source is located at a transverse axis or a longitudinal axis of the deposition mask 50.

The deposition mask 50 is a mask structure which is used for forming a particular pattern of a deposition layer 60, for example, an organic layer, in an electronic device, such as a display device, a lighting device, a semiconductor device, etc. by using the deposition apparatus 10. The deposition mask 50 may be deposition masks 100, 300, 400, and 500 according to the following embodiments.

The deposition mask 50 includes two or more openings 52. In a deposition process using the deposition apparatus 10, the deposition material 35 supplied from the deposition source 40 may pass through the openings 52 of the deposition mask 50 and then be deposited on the substrate 20.

The openings 52 included in the deposition mask 50 have a masking pattern corresponding to a particular pattern of the deposition layer 60. The number, arranged positions, and shapes of the openings 52 included in the deposition mask 50 are described as examples, but the present embodiments are not limited thereto.

In the deposition apparatus 10, the deposition angle, which is formed by a deposition path from the deposition source 40 with reference to a vertical line, increases in a direction toward the outer edge of a deposition surface of the substrate 20. In a deposition process to which the deposition mask 50 is applied, all the openings 52 of the deposition mask 50 cannot be disposed vertically under the deposition source 40. Therefore, the deposition masks 100, 300, and 400 and the deposition apparatus 10 including the same masks applied thereto according to embodiments may adjust the step heights of the openings 52 depending on the deposition surface of the substrate 20 in order to improve deposition uniformity.

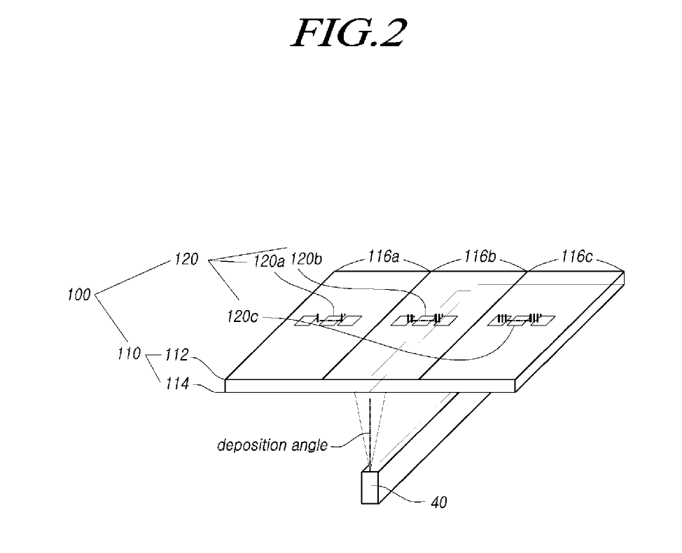

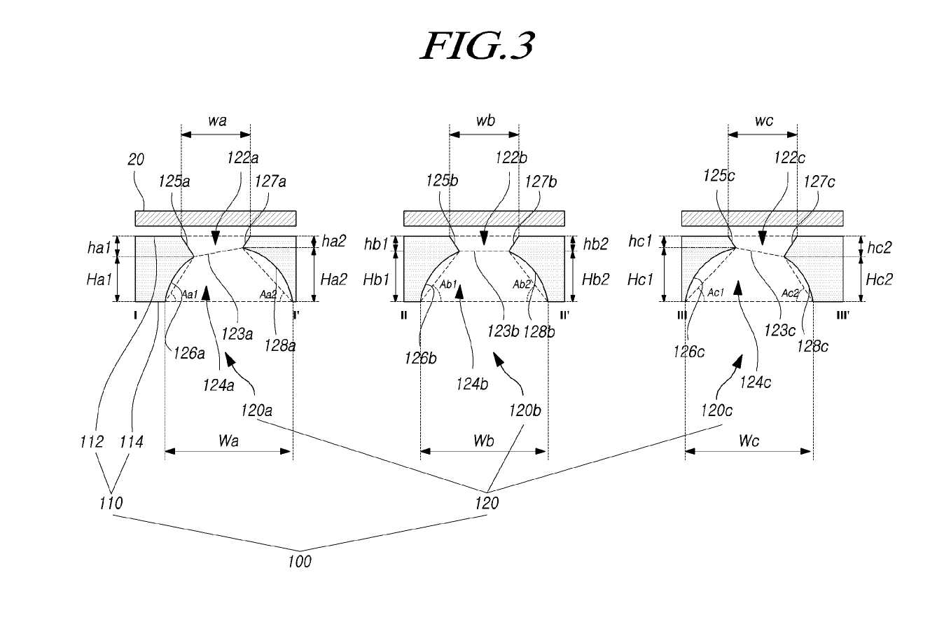

FIG. 2 is a perspective view of a deposition mask according to another embodiment, and FIG. 3 is a view showing a cross section taken along I-I′, II-II′, and III-III′ of FIG. 2 and a cross section of a substrate.

Referring to FIG. 2, a deposition mask 100 according to another embodiment may generally have a quadrangular shape, but the shape thereof is not limited thereto. Further, the deposition mask 100 can have various shapes, such as circle or hexagon.

The deposition mask 100 includes a base member 110 and one or more openings 120 extending through the base member 110.

The base member 110 may be a metal or an alloy. For example, the base member 110 may include at least one selected from the group consisting of iron, nickel, copper, tin, gold, stainless steel (SUS), an Invar alloy, an Inconel alloy, a Kovar alloy, an iron alloy, a nickel alloy, a nickel-phosphorus alloy (NI—P), and a nickel-phosphorus-polytetrafluoroethylene (NI—P-PTFE) alloy, but the present embodiment is not limited thereto.

The base member 110 includes a first surface 112 and a second surface 114 and is divided into at least a first region 116a, a second region 116b, and a third region 116c. The first surface 112 of the base member 110 is oriented toward the substrate 20 and the second surface 114 thereof is oriented toward the deposition source 40. As illustrated in FIG. 2, when the deposition source 40 is a linear source, the deposition source 40 is disposed at a position corresponding to the second region 116b. The first region 116a and the third region 116c are located at both sides of the deposition source 40.

The openings 120 include a first opening to a third opening 120a, 120b, and 120c which are disposed at the first region to the third region 116a, 116b, and 116c, respectively. The second opening 120b disposed at the second region 116b has a relatively small deposition angle from the deposition source 40. However, the first opening 120a and the third opening 120c, which are located at the first region 116a and the third region 116c, respectively, can have relatively large deposition angles from the deposition source 40.

Referring to FIG. 3, each of the first, second and third openings 120a, 120b, and 120c includes a first surface hole 122a, 122b, or 122c and a second surface hole 124a, 124b, or 124c which extend through the first surface 112 and the second surface 114 of the base member 110 and are mutually open to each other, respectively (e.g., the hole are connected or in communication with each other). The first surface holes 122a, 122b, and 122c can have narrower widths from the first surface 112 to borders 123a, 123b, and 123c (e.g., an imaginary dividing line between the two holes, where the two holes meet) in a thickness direction of the base member 110. The second surface holes 124a, 124b, and 124c can have narrower widths from the second surface 114 to the borders 123a, 123b, and 123c in a thickness direction of the base member 110.

In each of the first opening to the third opening 120a, 120b, and 120c, a step height (hax, hbx, and hcx, where x=1 or 2) of the first surface hole 122a, 122b, or 122c can be smaller than a step height (Hax, Hbx, and Hcx, where x=1 or 2) of the second surface hole 124a, 124b, or 124c. The step heights (hax, hbx, and hcx, where x=1 or 2) of the first surface holes 122a, 122b, and 122c of the first, second and third openings 120a, 120b, and 120c are small, so that a shadow effect is generally minimized.

The step heights hb1 and hb2 of both side surfaces 125b and 127b of the first surface hole 122b of the second opening 120b disposed at the second region 116b located between the first region 116a and the third region 116c may be physically or substantially equal.

Both side surfaces of the first surface hole 122a or 122c of each of the first opening 120a and the third opening 120c, which are located at the first region 116a and the third region 116c, respectively, may have different step heights. The step height ha2 or hc1 of a side surface 127a or 125c in a direction toward (e.g., closest to) the second opening among both side surfaces of the first surface hole 122a or 122c of each of the first opening 120a and the third opening 120c can be smaller than the step height ha1 or hc2 of a side surface 125a or 127c in a direction opposite to the second opening.

That is, the step heights ha1 and ha2 of both side surfaces 125a and 127a of the first surface hole 122a of the first opening 120a located at the first region 116a may be different. The step height ha2 of the side surface 127a in a direction toward the second opening among both side surfaces 125a and 127a of the first surface hole 122a of the first opening 120a may be smaller than the step height ha1 of the side surface 125a in a direction opposite to the second opening.

The step height ha2 of the side surface 127a, which is in a direction toward the second opening, of the first surface hole 122a of the first opening 120a can be smaller than the step heights hb1 and hb2 of both side surfaces 125b and 127b of the first surface hole 122b of the second opening 120b. The step height ha1 of the side surface 125a, which is in a direction opposite to the second opening, of the first surface hole 122a of the first opening 120a may be larger than the step heights hb1 and hb2 of both side surfaces 125b and 127b of the first surface hole 122b of the second opening 120b.

The step heights hc1 and hc2 of both side surfaces 125c and 127c of the first surface hole 122c of the third opening 120c located at the third region 116c may be different. The step height hc1 of the side surface 125c in a direction toward the second opening among both side surfaces 125c and 127c of the first surface hole 122c of the third opening 120c can be smaller than the step height hc2 of the side surface 127c in a direction opposite to the second opening.

The step height hc1 of the side surface 125c, which is in a direction toward the second opening, of the first surface hole 122c of the third opening 120c may be smaller than the step heights hb1 and hb2 of both side surfaces 125b and 127b of the first surface hole 122b of the second opening 120b. The step height hc2 of the side surface 127c, which is in a direction opposite to the second opening, of the first surface hole 122c of the third opening 120c may be larger than the step heights hb1 and hb2 of both side surfaces 125b and 127b of the first surface hole 122b of the second opening 120b.

The step heights Hb1 and Hb2 of both side surfaces 126b and 128b of the second surface hole 124b of the second opening 120b disposed at the second region 116b located between the first region 116a and the third region 116c can be physically or substantially the same.

Both side surfaces of the second surface hole 124a or 124c of each of the first opening 120a and the third opening 120c, which are located at the first region 116a and the third region 116c, respectively, may have different step heights. The step height Ha2 or Hc1 of a side surface 128a or 126c in a direction toward the second opening among both side surfaces of the second surface hole 124a or 124c of each of the first opening 120a and the third opening 120c may be larger than the step height Ha1 or Hc2 of a side surface 126a or 128c in a direction opposite to the second opening.

That is, the step heights Ha1 and Ha2 of both side surfaces 126a and 128a of the second surface hole 124a of the first opening 120a located at the first region 116a may be different. The step height Ha2 of the side surface 128a in a direction toward the second opening among both side surfaces 126a and 128a of the second surface hole 124a of the first opening 120a can be larger than the step height Ha1 of the side surface 126a in a direction opposite to the second opening.

The step height Ha2 of the side surface 128a, which is in a direction toward the second opening, of the second surface hole 124a of the first opening 120a may be larger than the step heights Hb1 and Hb2 of both side surfaces 126b and 128b of the second surface hole 124b of the second opening 120b. The step height Hal of the side surface 126a, which is in a direction opposite to the second opening, of the second surface hole 124a of the first opening 120a may be smaller than the step heights Hb1 and Hb2 of both side surfaces 126b and 128b of the second surface hole 124b of the second opening 120b.

The step heights Hc1 and Hc2 of both side surfaces 126c and 128c of the second surface hole 124c of the third opening 120c located at the third region 116c can be different. The step height Hc1 of the side surface 126c, which is in a direction toward the second opening among both side surfaces 126c and 128c of the second surface hole 124c of the third opening 120c may be larger than the step height Hc2 of the side surface 128c in a direction opposite to the second opening.

The step height Hc1 of the side surface 126c, which is in a direction toward the second opening, of the second surface hole 124c of the third opening 120c may be larger than the step heights Hb1 and Hb2 of both side surfaces 126b and 128b of the second surface hole 124b of the second opening 120b. The step height Hc2 of the side surface 128c, which is in a direction opposite to the second opening, of the second surface hole 124c of the third opening 120c can be smaller than the step heights Hb1 and Hb2 of both side surfaces 126b and 128b of the second surface hole 124b of the second opening 120b.

In the first, second and third openings 120a, 120b, and 120c, opening widths Wa, Wb, and Wc exposed to the second surface of the second surface holes 124a, 124b, and 124c may be wider than opening widths wa, wb, and wc exposed to the first surface of the first surface holes 122a, 122b, and 122c. The opening widths Wa, Wb, and Wc exposed to the second surface of the second surface holes 124a, 124b, and 124c are wider than the opening widths wa, wb, and wc exposed to the first surface of the first surface holes 122a, 122b, and 122c. Therefore, the deposition material 35 supplied from the deposition source 40 may sufficiently pass through the first, second and third openings 120a, 120b, and 120c.

The first, second and third openings 120a, 120b, and 120c can have the same opening width wa, wb, and wc exposed to the first surface of the first surface holes 122a, 122b, and 122c. Through this configuration, the same amounts of the deposition material 35 supplied from the deposition source 40 may pass through the first, second and third openings 120a, 120b, and 120c, respectively. The first, second and third openings 120a, 120b, and 120c can have the same opening width Wa, Wb, and Wc exposed to the second surface of the second surface holes 124a, 124b, and 124c.

For example, when R, G, and B light emitting layers in an organic light emitting display apparatus are deposited in the deposition apparatus 10, the R light emitting layers, the G light emitting layers, and the B light emitting layers may have the same light emitting areas, respectively. The first surface holes 122a, 122b, and 122c of the same light emitting layers may have the same opening width wa, wb, and wc, and may be located at different positions, that is, at the first region 116a, the second region 116b, and the third region 116c, respectively.

It has been described above that the first, second and third openings 120a, 120b, and 120c can have the same opening width wa, wb, and wc exposed to the first surface of the first surface holes 122a, 122b, and 122c. However, the first, second and third openings 120a, 120b, and 120c may have at least one different opening width among the opening widths wa, wb, and wc exposed to the first surface of the first surface holes 122a, 122b, and 122c according to a pattern of the deposition layer. When at least one among the opening widths wa, wb, and wc exposed to the first surface of the first surface holes 122a, 122b, and 122c is different, one among the opening widths Wa, Wb, and Wc exposed to the second surface of the second surface holes 124a, 124b, and 124c can be different at the same ratio, as well.

For example, when R, G, and B light emitting layers in an organic light emitting display apparatus are deposited in the deposition apparatus 10, the light emitting areas of the R, G, and B light emitting layers may be different from each other. Then, the opening widths wa, wb, and wc of the first surface holes 122a, 122b, and 122c can be different at the same ratio as the light emitting areas of the R, G, and B light emitting layers.

Both side surfaces of each of the first surface holes 122a, 122b, and 122c of the first, second and third openings 120a, 120b, and 120c may have a linear sectional shape, but are not limited thereto, and may be a curved surface. Both side surfaces of each of the second surface holes 124a, 124b, and 124c of the first, second and third openings 120a, 120b, and 120c may be a curved surface, but are not limited thereto, and may have a linear sectional shape . For example, the first, second and third openings can each have a cross-section having an hourglass shape.

In consideration of a process of manufacturing the first surface holes 122a, 122b, and 122c and the second surface holes 124a, 124b, and 124c as described later, both side surfaces of each of the first surface holes 122a, 122b, and 122c of the first, second and third openings 120a, 120b, and 120c can have a linear sectional shape, and both side surfaces of each of the second surface holes 124a, 124b, and 124c of the first, second and third openings 120a, 120b, and 120c may be a curved surface.

The first surface holes 122a, 122b, and 122c of the first, second and third openings 120a, 120b, and 120c are at the same location of the corresponding areas to each other (e.g., each located in the center of their corresponding region), but the second surface holes 124a, 124b, and 124c can be at different positions of corresponding areas (e.g., at shifted positions within their corresponding region). As illustrated in FIG. 3, the second surface hole 124a of the first opening 120a can be biased toward the second opening with reference to the first surface hole 122a of the first opening 120a. The second surface hole 124c of the third opening 120c can be biased toward the second opening with reference to the first surface hole 122c of the third opening 120c.

The inclined angles Ab1 and Ab2 from the second surface 114 to the border 123b of both side surfaces 126b and 128b of the second surface hole 124b of the second opening 120b can be the equal to each other. The inclined angle implies an angle which a straight line established from the second surface 114 to the border 123 makes with respect to a horizontal plane. The inclined angles from the second surface 114 to the border 123a or 123c of both side surfaces of the second surface hole 124a or 124c of each of the first opening 120a and the third opening 120c can be different from each other.

That is, the inclined angles Aa1 and Aa2 from the second surface 114 to the border 123a of both side surfaces 126a and 128a of the second surface hole 124a of the first opening 120a can be different from each other. The inclined angles Ac1 and Ac2 from the second surface 114 to the border 123c of both side surfaces 126c and 128c of the second surface hole 124c of the third opening 120c can be different from each other.

The inclined angle Aa2 or Ac1 of the side surface 128a or 126c in a direction toward the second opening among both side surfaces of the second surface hole 124a or 124c of each of the first opening 120a and the third opening 120c may be smaller than the inclined angles Ab1 and Ab2 of both side surfaces 126b and 128b of the second opening 120b. Therefore, even when the deposition angle increases in the direction toward the outer edge of the deposition surface of the substrate 20, the deposition surface may not be blocked by the openings 120.

In the deposition mask and the deposition apparatus using the same according to the embodiments described above, the step heights of first surface holes are configured to be small depending on the positions in the deposition mask, according to a deposition angle increasing in a direction toward the outer edge of the deposition surface of the substrate, so that a shadow effect affecting the center and outer edge of the deposition surface of the substrate can be minimized.

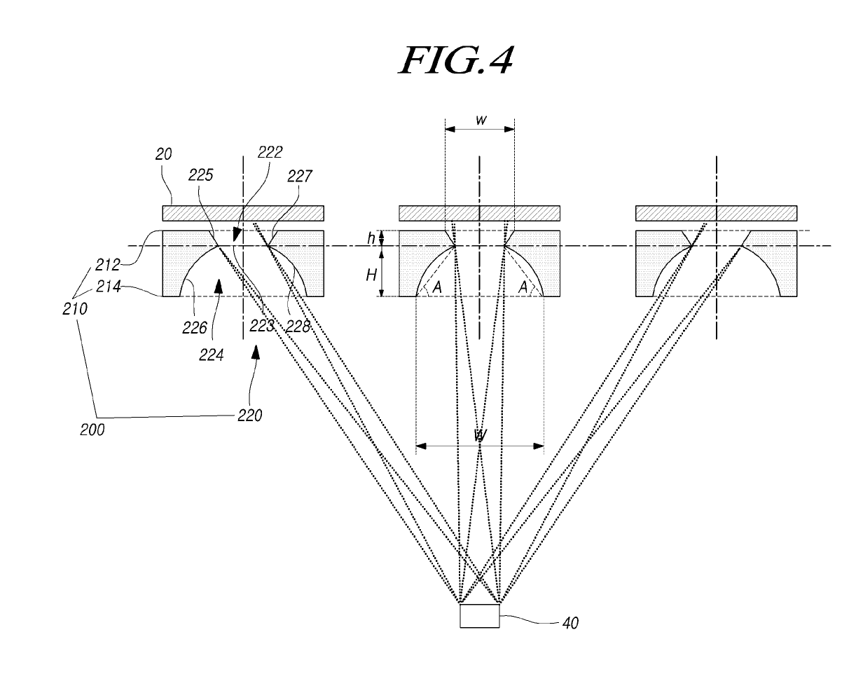

FIG. 4 illustrates a cross section of a deposition mask, a cross section of a substrate, and a deposition path according to a comparative example.

Referring to FIG. 4, a deposition mask 200 according to a comparative example includes: a base member 210 including a first surface 212 and a second surface 214; and two or more openings 220 extending through the base member 210.

The openings 220 include first surface holes 222 and second surface holes 224 which extend through the first surface 212 and the second surface 214 of the base member 210 and are mutually open to each other. The openings 220 have the same step height h of both side surfaces 225 and 227 and the same opening width w of the first surface holes 222, the same step height H of both side surfaces 226 and 228 and the same opening width W of the second surface holes 224, and the same inclined angle A from the second surface 214 to a border 223 of both side surfaces.

The incident angle of the deposition material 35 increases in a direction toward the outer edge of the substrate 20 from the deposition source 40. The deposition mask 200 according to the comparative example has the same step height h of the first surface holes 222 and the same step height H of the second surface holes 224 of the openings 220 at all the positions of the mask. Therefore, the shadow effect increases in a direction toward the outer edge of the substrate 20 from the deposition source 40. Therefore, in order to prevent degradation of deposition uniformity due to the shadow effect, the opening is made to have an increased opening width, and thus have an increased deposition margin.

However, the deposition mask 200 according to the comparative example has the same opening width w of the first surface holes 222 and the same opening width W of the second surface holes 224 of the openings 220 at all the positions of the mask. Therefore, the deposition uniformity may degrade due to the shadow effect.

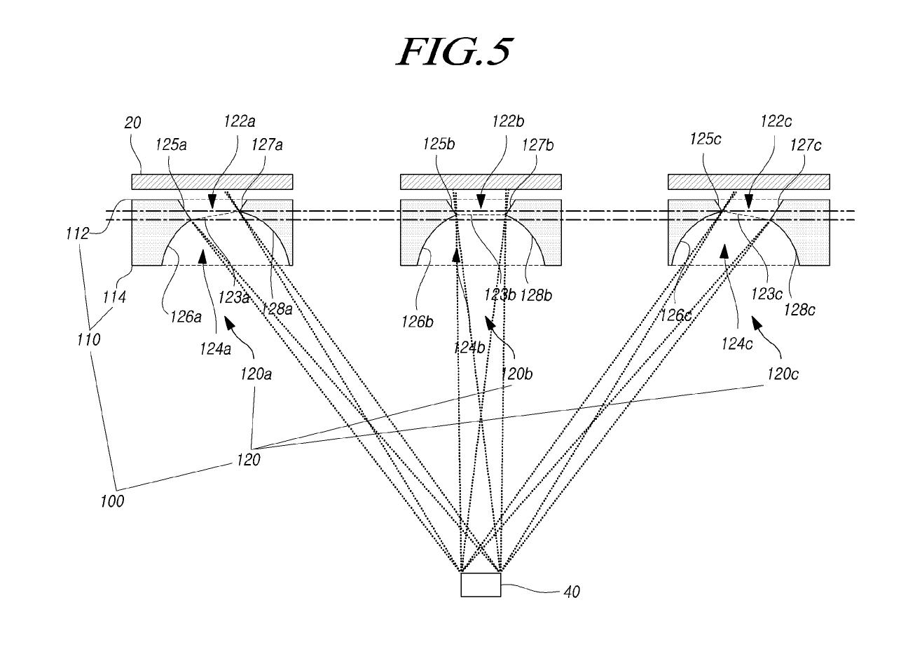

FIG. 5 illustrates a deposition path of the deposition mask illustrated in FIG. 3.

Referring to FIGS. 3 and 5, the first, second and third openings 120a, 120b, and 120c have the same opening width Wa, Wb, and Wc, which are exposed to the second surface 114, of the second surface holes 124a, 124b, and 124c. However, the step height ha2 or hc1 of the side surface 127a or 125c in a direction toward the second opening among both side surfaces of the first surface hole 122a or 122c of each of the first opening 120a and the third opening 120c is smaller than the step heights hb1 and hb2 of both side surfaces 125a and 127c of the first surface hole 122b of the second opening 120b.

In the deposition mask 100 illustrated in FIG. 3, the step heights of the side surfaces of the openings 120, which extend through the first surface 112 and the second surface 114 of the base member 110, are adjusted for each position in the deposition mask 100, corresponding to a deposition angle varying depending on positions in the substrate 20 to be subject to deposition. Therefore, the shadow effect increasing in a direction toward the outer edge of the substrate 20 from the deposition source 40 can be minimized.

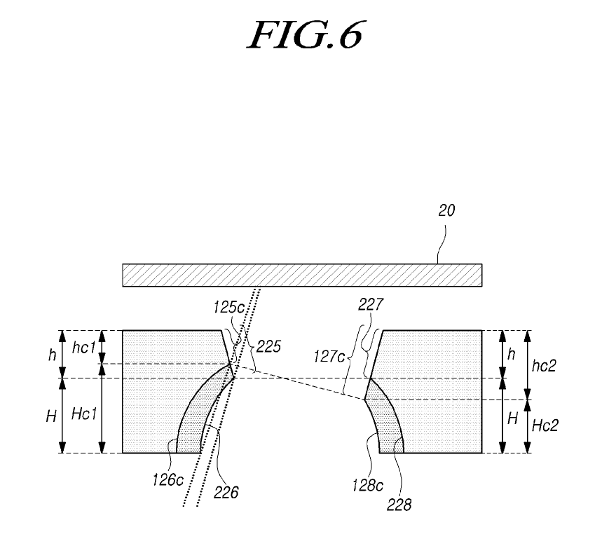

FIG. 6 illustrates a comparison of shadow effects according to a difference between step heights of side surfaces of third openings of the deposition mask illustrated in FIG. 3 and the deposition mask illustrated in FIG. 4.

Referring to FIGS. 3 and 6, the step height hc1 of the side surface 125c, which is in a direction toward (e.g., nearest) the second opening, of the first surface hole 122c of the third opening 120c is smaller than the step heights hb1 and hb2 of both side surfaces 125b and 127b of the first surface hole 122b of the second opening 120b. Therefore, the deposition mask according to the present embodiments can minimize a shadow effect compared with the deposition mask 200 of FIG. 4 in which the side surfaces of the openings all have the same step height or depth.

In addition, as in the deposition mask 100 described above with reference to FIG. 3, the step height ha2 of the side surface 127a, which is in a direction toward the second opening, of the first surface hole 122a of the first opening 120a is smaller than the step heights hb1 and hb2 of both side surfaces 125b and 127b of the first surface hole 122b of the second opening 120b. Therefore, the deposition mask according to the present embodiments can minimize a shadow effect compared with the deposition mask 200 of FIG. 4, in which the side surfaces of the openings all have the same step height or depth.

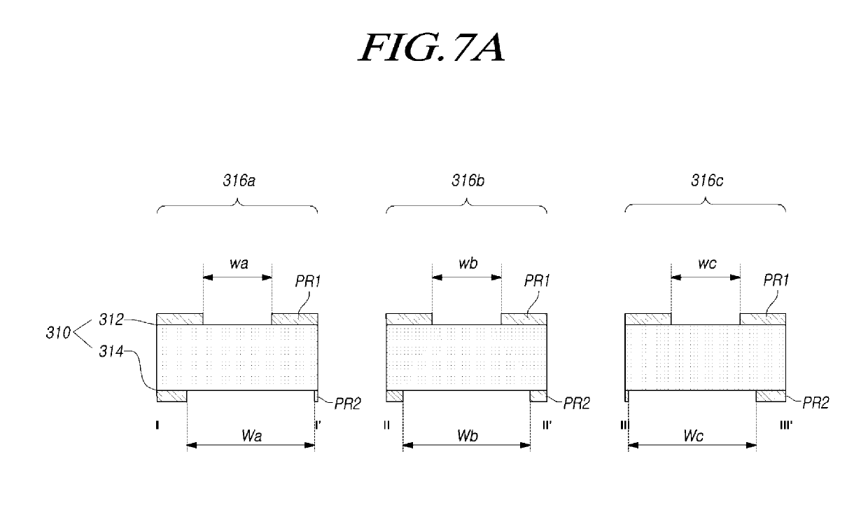

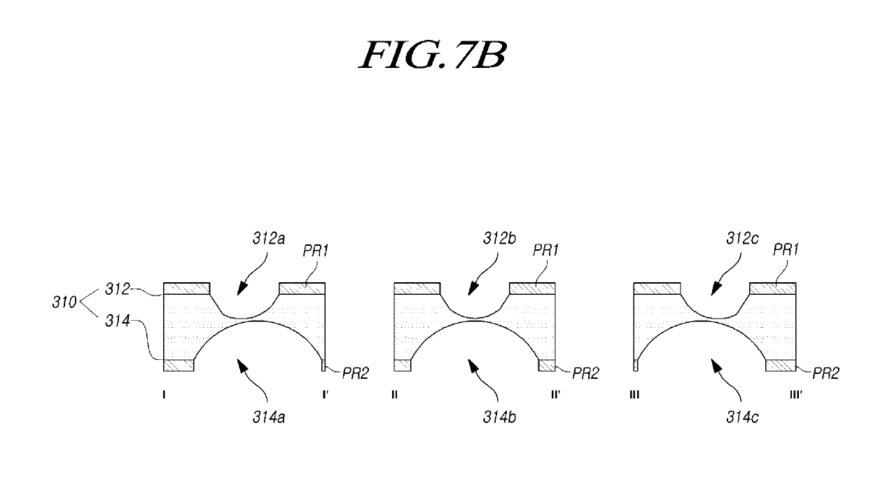

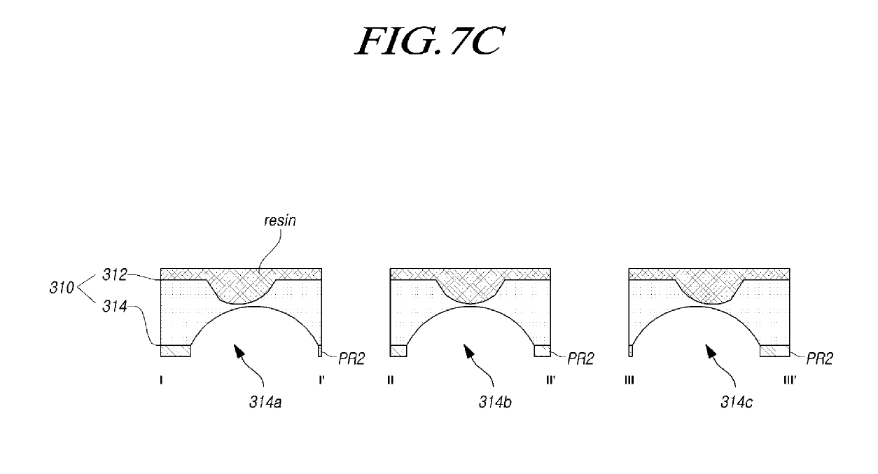

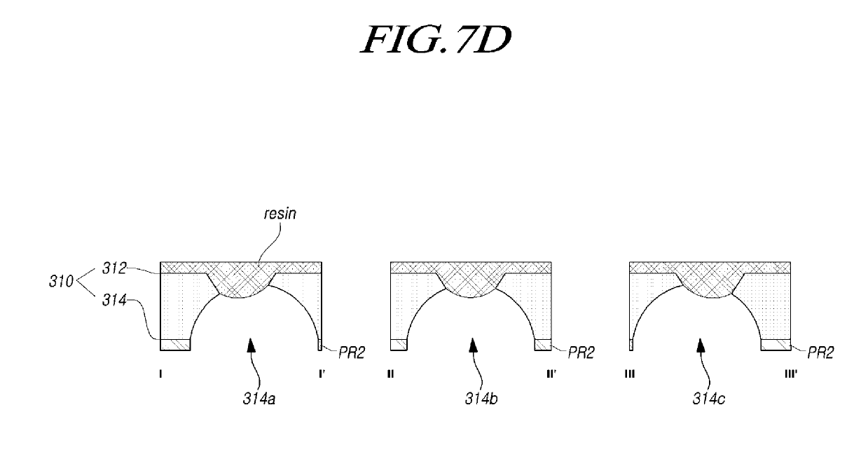

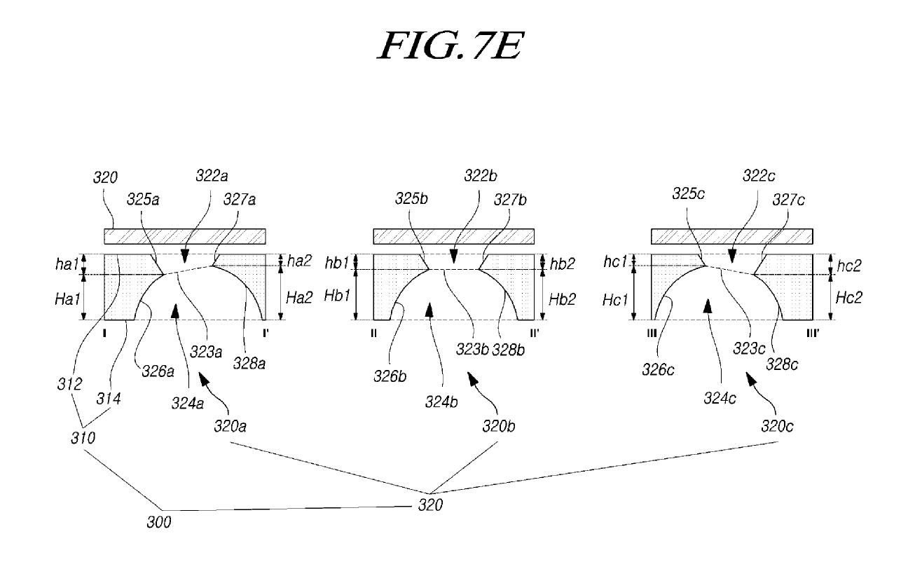

The openings included in the above deposition mask may be formed by a photo-etching method in which a metal thin film is light-exposed by using a pattern of a photoresist film and then etched, an electro-forming method in which a desired pattern is electroplated on a glass-disk and then delaminated, etc. A method for manufacturing a deposition mask according to another embodiment using a photo-etching method will be described with reference to FIGS. 7A to 7E, but the present disclosure is not limited thereto.

FIGS. 7A to 7E are diagrams showing a method of manufacturing a deposition mask according to another embodiment.

Referring to FIG. 7A, a base member 310 for manufacturing a deposition mask is prepared. The base member 310 can be a metal or an alloy, as described above.

A first photoresist PR1 having a particular pattern which is substantially the same as that of a deposition layer to be formed is formed on a first surface 312 of the base member 310. For example, the base member 310 is divided into a first region to a third region 316a, 316b, and 316c, and first photoresists PR1 having a first opening width wa, a second opening width wb, and a third opening width wc, are coated on the first region to the third region 316a, 316b, and 316c, respectively.

Second photoresists PR2 having a fourth opening width to a sixth opening width Wa, Wb, and Wc, which are located at positions corresponding to the first opening width to the third opening width wa, wb, and wc, have the same pattern as the particular pattern described above, and are wider than the first opening width to the third opening width wa, wb, and wc, respectively, are formed on the first region to the third region 316a, 316b, and 316c of a second surface 314 of the base member 310. The fifth opening width Wb is located at the same position as that of the second opening width wb. However, the fourth opening width Wa and the sixth opening width Wc are biased (e.g., shifted) further toward the fifth opening width Wb than the same positions as those of the first opening width wa and the third opening width wc.

That is, when a deposition mask is manufactured by a general deposition mask manufacturing method, e.g., a bilateral etching or a 2-step etching, the centers of particular patterns of the photoresists PR1 and PR2 generally match each other at the same location of both surfaces 312 and 314 of the base member 310. However, in a method for manufacturing a deposition mask according to another embodiment, the central axes of the particular patterns of the photoresists gradually vary in a direction toward the outer edge thereof.

Referring to FIG. 7B, the first surface 312 and the second surface 314 of the base member 310 are bilaterally etched using an etching solution. Through the bilateral etching process, the same first holes 312a, 312b, and 312c are formed in the first surface 312, and the same second holes 314a, 314b, and 314c are formed in the second surface 314. The first holes 312a, 312b, and 312c do not communicate with the second holes 314a, 314b, and 314c.

Referring to FIG. 7C, the first photoresists PR1 are removed from the first surface 312 and the second photoresists PR2 are maintained on the second surface 314. Then, resins are generally disposed on the first surface 312. The resins are applied to the entirety of the first surface 312 including the first holes 312a, 312b, and 312c.

Referring to FIG. 7D, an additional etching process is performed on only the second surface 314 of the base member 310. Then, the first holes 312a, 312b, and 312c communicate with the second holes 314a, 314b, and 314c, respectively. The first holes 312a, 312b, and 312c can be found with reference to FIG. 7B.

Referring to FIG. 7E, the resins are removed from the first surface 312 and then the deposition mask 300 according to another embodiment is completed.

In the deposition mask 300, like the deposition mask 100 described with reference to FIG. 3, the step height ha2 or hc1 of a side surface 327a or 325c in a direction toward a second opening among both side surfaces of a first surface hole 322a or 322c of each of a first opening 320a and a third opening 320c is smaller than the step heights hb1 and hb2 of both side surface 325b and 327b of a first surface hole 322b of the second opening 320b. Therefore, the deposition mask 300 can minimize the shadow effect.

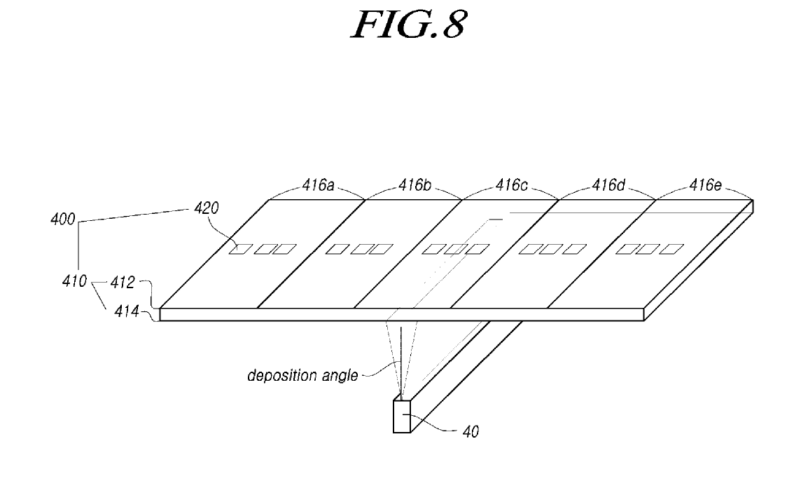

FIG. 8 is a perspective view of a deposition mask according to another embodiment and illustrates relative positions of the deposition mask and a deposition source.

Referring to FIG. 8, the deposition mask 400 according to another embodiment includes a base member 410 and an opening 420 extending through the base member 410.

The base member 410 includes a first surface 412 and a second surface 414 and is divided into at least a first region to a fifth region 416a, 416b, 416c, 416d, and 416e. As illustrated in FIG. 8, when a deposition source 40 is a linear source, the deposition source 40 is disposed at a position corresponding to the third region 416c. The first region 416a and the second region 416b are located at one side of the deposition source 40, and the fourth region 416d and the fifth region 416e are located at the other side of the deposition source 40.

The step heights of both side surfaces of a first surface hole of each of openings located at the third region 416c can be the same. Also, the step heights of side surfaces in a direction toward the third region 416c among both side surfaces of first surface holes of openings located at the first region 416a and the second region 416b become relatively smaller. In the same way, the step heights of side surfaces in a direction toward the third region 416c among both side surfaces of first surface holes of openings located at the fourth region 416d and the fifth region 416e become relatively smaller.

The deposition mask 400 has been described to be divided into the five regions 416a, 416b, 416c, 416d, and 416e. However, a deposition mask can be divided into 2N+1 number (N is a natural number larger than 1) of regions. Further, the step heights of both side surfaces of a first surface hole of each of openings located at the N+1-th region are the same, but the step heights of side surfaces in a direction toward the N+1-th region among both side surfaces of first surface holes of openings, which are located at the first region to the N-th region, respectively, become gradually and relatively smaller. In the same way, the step heights of side surfaces in a direction toward the N+1-th region among both side surfaces of first surface holes of openings located at the N+2th region to the 2N+1-th region become gradually and relatively smaller.

In the above embodiments, the openings including the first surface holes, both side surfaces of which have the same step height, are located at the center of the base member. However, the openings can be located at one side of the base member. For example, in a deposition apparatus in which a deposition source is disposed at one side of a base member, openings including first surface holes, both side surfaces of which have the same step height, may be located at one side of the base member.

In the above embodiments, openings including first surface holes, both side surfaces of which have the same step height are located at only one region of a base member. However, the openings may be located at two or more regions of the base member. For example, when a deposition source is a linear source and two or more of the deposition sources are disposed in a deposition apparatus, the step heights of both side surfaces of first surface holes of openings located at positions at which the deposition sources are arranged can be the same.

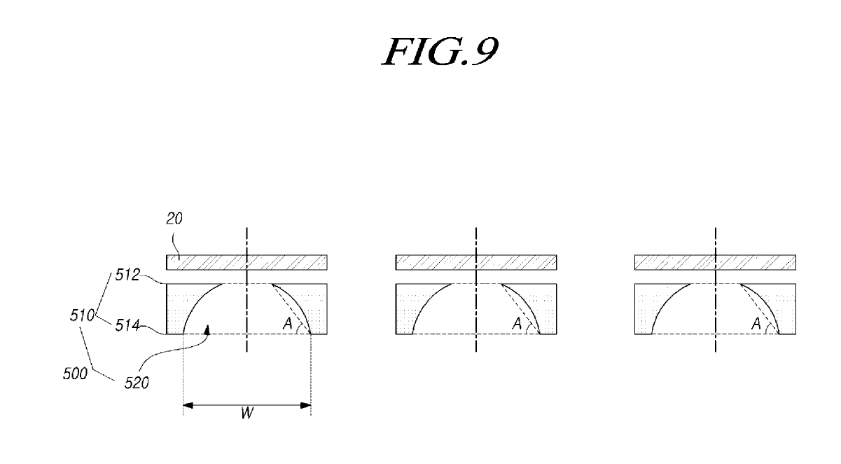

FIG. 9 is a cross sectional view of a deposition mask according to another embodiment.

Referring to FIG. 9, the deposition mask 500 according to another embodiment includes a base member 510 and two or more openings 520 extending through the base member 510.

The base member 510 includes a first surface 512 and a second surface 514. The openings 520 include holes corresponding to the second surface holes described with reference to FIG. 3, but do not include holes corresponding to the first surface holes. The openings 520 have the same opening width W and the same inclined angle A.

The base member 510 can have a thickness suitable for forming the openings 520 by performing a unidirectional etching process on the second surface 314 of FIG. 7A to 7C. For example, the thickness of the base member 510 can be, for example, equal to or smaller than 20 μm, but the thickness is not limited thereto.

In the deposition mask and the deposition apparatus using the same according to the embodiments described above, the step heights of first surface holes are configured to be small depending on positions in the deposition mask, according to a deposition angle increasing in a direction toward the outer edge of the deposition surface of the substrate, so that a shadow effect affecting the center and outer edge of the deposition surface of the substrate may be minimized.

The deposition mask and the deposition apparatus using the same according to the embodiments described above can minimize a shadow effect during a deposition process, and thus improve the deposition uniformity.

The features, structures, effects, etc. described in the above embodiment are included in at least one embodiment of the present disclosure, and are not limited by only one embodiment. Further, the features, structures, effects, etc. exemplified in each embodiment described above can be implemented through combination and modification of other embodiments by a person skilled in a field to which the embodiments belong. Therefore, the contents relating to the modification and the combination should be construed as being included in the scope of the present disclosure.

In addition, embodiments described above are merely examples, and the present disclosure is not limited thereto. Further, those skilled in the art will appreciate that various modifications and applications not exemplified above are possible, without departing from the scope and spirit of the present embodiment. For example, each element specifically described in the embodiments can be modified and then implemented. In addition, a difference relating to the modification and application should be construed as being included in the scope of the present disclosure regulated by the accompanying claims.

What is claimed is:

1. A deposition mask comprising:
a base member including a first surface and a second surface, the base member being divided into a first region, a second region and a third region;
a first opening in the first region and comprising:
a first surface hole of the first opening extending through the first surface of the base member,
a second surface hole of the first opening extending through the second surface of the base member and in communication with the first surface hole of the first opening,
a width of the first surface hole of the first opening gradually decreases toward a border between the first surface hole of the first opening and the second surface hole of the first opening, and
a width of the second surface hole of the first opening gradually decreases toward the border between the first surface hole of the first opening and the second surface hole of the first opening;
a second opening in the second region and comprising:
a first surface hole of the second opening extending through the first surface of the base member,
a second surface hole of the second opening extending through the second surface of the base member and in communication with the first surface hole of the second opening,
a width of the first surface hole of the second opening gradually decreases toward a border between the first surface hole of the second opening and the second surface hole of the second opening, and
a width of the second surface hole of the second opening gradually decreases toward the border between the first surface hole of the second opening and the second surface hole of the second opening; and
a third opening in the third region and comprising:
a first surface hole of the third opening extending through the first surface of the base member,
a second surface hole of the third opening extending through the second surface of the base member and in communication with the first surface hole of the third opening,
a width of the first surface hole of the third opening gradually decreases toward a border between the first surface hole of the third opening and the second surface hole of the third opening, and
a width of the second surface hole of the third opening gradually decreases toward the border between the first surface hole of the third opening and the second surface hole of the third opening,
wherein step heights of both side surfaces of the first surface hole of the second opening are substantially equal to each other,
wherein a step height of a side surface of the first surface hole in the first opening adjacent to the second opening is smaller than the step heights of both side surfaces of the first surface hole in the second opening,
wherein a step height of a side surface of the first surface hole in the third opening adjacent to the second opening is smaller than the step heights of both side surfaces of the first surface hole in the second opening, and
wherein the second region is located between the first region and the third region.

2. The deposition mask of claim 1, wherein each of the first, second and third openings has a cross-section having an hourglass shape.

3. The deposition mask of claim 2, wherein the hourglass shape of the first opening in the first region leans away from the second opening in the second region relative to the second surface of the base member, and
wherein the hourglass shape of the third opening in the third region leans away from the second opening in the second region relative to the second surface of the base member.

4. The deposition mask of claim 1, wherein a depth of the first surface hole in the first opening is smaller than a depth of the second surface hole in the first opening,
wherein a depth of the first surface hole in the second opening is smaller than a depth of the second surface hole in the second opening, and
wherein a depth of the first surface hole in the third opening is smaller than a depth of the second surface hole in the third opening.

5. The deposition mask of claim 1, wherein a lowermost width of the first opening is wider than an uppermost width of the first opening,
wherein a lowermost width of the second opening is wider than an uppermost width of the second opening, and
wherein a lowermost width of the third opening is wider than an uppermost width of the third opening.

6. The deposition mask of claim 1, wherein an uppermost width of the first opening, an uppermost width of the second opening and an uppermost width of the third opening are substantially equal to each other.

7. The deposition mask of claim 1, wherein an lowermost width of the first opening, a lowermost width of the second opening and a lowermost width of the third opening are substantially equal to each other.

8. The deposition mask of claim 1, wherein both side surfaces of the first surface hole in the first opening are flat,
wherein both side surfaces of the first surface hole in the second opening are flat,
wherein both side surfaces of the first surface hole in the third opening are flat,
wherein both side surfaces of the second surface hole in the first opening are curved,
wherein both side surfaces of the second surface hole in the second opening are curved, and
wherein both side surfaces of the second surface hole in the third opening are curved.

9. The deposition mask of claim 1, wherein inclined angles of both side surfaces of the second surface hole of the second opening are substantially equal to each other,
wherein inclined angles of both side surfaces of the second surface hole of the first opening are different from each other, and
wherein inclined angles of both side surfaces of the second surface hole of the third opening are different from each other.

10. The deposition mask of claim 1, wherein inclined angles of both side surfaces of the second surface hole in the second opening are steeper than both an inclined angle of a side surface of the second surface hole in the first opening that is closest to the second opening and an inclined angle of a side surface of the second surface hole in the third opening that is closest to the second opening.

11. A deposition apparatus comprising:
a chamber including a deposition workspace for a substrate;
a deposition source in the chamber and configured to supply a deposition material; and
a deposition mask comprising:
a base member including a first surface and a second surface, the base member being divided into a first region, a second region and a third region,
a first opening in the first region and comprising:
a first surface hole of the first opening extending through the first surface of the base member,
a second surface hole of the first opening extending through the second surface of the base member and in communication with the first surface hole of the first opening,
a width of the first surface hole of the first opening gradually decreases toward a border between the first surface hole of the first opening and the second surface hole of the first opening, and
a width of the second surface hole of the first opening gradually decreases toward the border between the first surface hole of the first opening and the second surface hole of the first opening,
a second opening in the second region and comprising:
a first surface hole of the second opening extending through the first surface of the base member,
a second surface hole of the second opening extending through the second surface of the base member and in communication with the first surface hole of the second opening,
a width of the first surface hole of the second opening gradually decreases toward a border between the first surface hole of the second opening and the second surface hole of the second opening, and
a width of the second surface hole of the second opening gradually decreases toward the border between the first surface hole of the second opening and the second surface hole of the second opening, and
a third opening in the third region and comprising:
a first surface hole of the third opening extending through the first surface of the base member,
a second surface hole of the third opening extending through the second surface of the base member and in communication with the first surface hole of the third opening,
a width of the first surface hole of the third opening gradually decreases toward a border between the first surface hole of the third opening and the second surface hole of the third opening, and
a width of the second surface hole of the third opening gradually decreases toward the border between the first surface hole of the third opening and the second surface hole of the third opening,
wherein step heights of both side surfaces of the first surface hole of the second opening are substantially equal to each other,
wherein a side surface of the first surface hole in the first opening adjacent to the second opening is smaller than both side surfaces of the first surface hole in the second opening,
wherein a side surface of the first surface hole in the third opening adjacent to the second opening is smaller than both side surfaces of the first surface hole in the second opening, and
wherein the second region is located between the first region and the third region.

12. The deposition apparatus of claim 11, wherein each of the first, second and third openings has a cross-section having an hourglass shape.

13. The deposition apparatus of claim 12, wherein the hourglass shape of the first opening in the first region leans away from the second opening in the second region relative to the second surface of the base member, and
wherein the hourglass shape of the third opening in the third region leans away from the second opening in the second region relative to the second surface of the base member.

14. The deposition apparatus of claim 11, wherein a depth of the first surface hole in the first opening is smaller than a depth of the second surface hole in the first opening,
wherein a depth of the first surface hole in the second opening is smaller than a depth of the second surface hole in the second opening, and
wherein a depth of the first surface hole in the third opening is smaller than a depth of the second surface hole in the third opening.

15. The deposition apparatus of claim 11, wherein a lowermost width of the first opening is wider than an uppermost width of the first opening,
wherein a lowermost width of the second opening is wider than an uppermost width of the second opening, and
wherein a lowermost width of the third opening is wider than an uppermost width of the third opening.

16. The deposition apparatus of claim 11, wherein an uppermost width of the first opening, an uppermost width of the second opening and an uppermost width of the third opening are substantially equal to each other.

17. The deposition apparatus of claim 11, wherein an lowermost width of the first opening, a lowermost width of the second opening and a lowermost width of the third opening are substantially equal to each other.

18. The deposition apparatus of claim 11, wherein both side surfaces of the first surface hole in the first opening are flat,
wherein both side surfaces of the first surface hole in the second opening are flat,
wherein both side surfaces of the first surface hole in the third opening are flat,
wherein both side surfaces of the second surface hole in the first opening are curved,
wherein both side surfaces of the second surface hole in the second opening are curved, and
wherein both side surfaces of the second surface hole in the third opening are curved.

19. The deposition apparatus of claim 11, wherein inclined angles of both side surfaces of the second surface hole of the second opening are substantially equal to each other,
wherein inclined angles of both side surfaces of the second surface hole of the first opening are different from each other, and
wherein inclined angles of both side surfaces of the second surface hole of the third opening are different from each other.

20. The deposition apparatus of claim 11, wherein inclined angles of both side surfaces of the second surface hole in the second opening are steeper than both an inclined angle of a side surface of the second surface hole in the first opening that is closest to the second opening and an inclined angle of a side surface of the second surface hole in the third opening that is closest to the second opening.
